(19) United States
(12) Patent Application Publication
(10) Pub. No.: US 2008/0278206 A1
(43) Pub. Date: Nov. 13, 2008

(54) DLL CIRCUIT

(75) Inventors: Tae-Kyun Kim, Ichon (KR); Kwang-Jun Cho, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMINCONDUCTOR, INC., Ichon (KR)

(21) Appl. No.: 11/961,805

(22) Filed: Dec. 20, 2007

(30) Foreign Application Priority Data
May 11, 2007 (KR) 10-2007-0046238

(51) Int. Cl. H03L 7/06

(52) U.S. Cl. 327/158

(57) ABSTRACT

A DLL circuit can enable a semiconductor integrated circuit to perform a stable data processing operation. The DLL circuit includes a phase splitter that controls the phase of a delay clock, thereby generating a rising clock and a falling clock, an amplifying unit that performs differential amplification on the rising clock and the falling clock in response to first and second duty control signals, thereby generating an amplified rising clock and an amplified falling clock, and a duty cycle control unit that detects the duty rates of the amplified rising clock and the amplified falling clock, thereby generating the first and second duty control signals.

### CROSS-REFERENCE TO RELATED PATENT APPLICATION

This application claims priority under 35 U.S.C. 119(a) of Korean Patent Application No. 10-2007-0046238, filed on May 11, 2007, in the Korean Intellectual Property Office, the contents of which are incorporated herein by reference as if set forth in full.

### BACKGROUND

1. Technical Field

The disclosure relates to a DLL (delay locked loop) circuit, and more particularly, to a DLL circuit capable of generating a clock signal having a constant duty cycle.

2. Related Art

In general, DLL circuits can be used to provide an internal clock whose phase leads the phase of a reference clock obtained by converting an external clock by a predetermined amount of time. When an internal clock used in a semiconductor integrated circuit is delayed by a clock buffer and a transmission line, a phase difference occurs between the external clock and the internal clock, which can result in a long output data access time. A DLL circuit can be used to solve this problem. A DLL circuit can control the internal clock, such that the phase of the internal clock leads the phase of the external clock by a predetermined amount of time, in order to lengthen an effective data output period.

In a semiconductor integrated circuit that outputs data at the rising time and the falling time of the external clock, such as a DDR (double data rate) SDRAM, the DLL circuit includes a phase splitter for generating a rising clock and a falling clock. However, it is actually difficult for the rising clock and the falling clock to have a constant duty cycle due to various factors, such as power supplied to the DLL circuit and characteristics of elements included in the DLL circuit. In order to provide a constant duty cycle.

Various techniques have been developed, however, a DLL circuit configured to implement such solutions will often still experience an inconstant duty cycle of a clock due to, for example, PVT (process, voltage, and temperature). When a clock having an inconstant duty cycle is transmitted to a data output buffer, the incidence of errors during a data output operation increases. Even worse, the data output operation may not be performed.

### SUMMARY

A DLL circuit capable of generating a rising clock and a falling clock having a constant duty cycle and enabling a semiconductor integrated circuit to stably process data is described herein.

In one aspect, a DLL circuit comprises: a phase splitter configured to control the phase of a delay clock, thereby generating a rising clock and a falling clock, an amplifying unit configured to perform differential amplification on the rising clock and the falling clock in response to first and second duty control signals, thereby generating an amplified rising clock and an amplified falling clock, and a duty cycle control unit configured to detect the duty rates of the amplified rising clock and the amplified falling clock, thereby generating the first and second duty control signals.

In another aspect a DLL circuit comprises: an amplifying unit configured to perform differential amplification on a rising clock and a falling clock in response to first and second duty control signals, thereby generating an amplified rising clock and an amplified falling clock, a duty cycle control unit configured to detect the duty rates of the amplified rising clock and the amplified falling clock, thereby generating the first and second duty control signals, and a clock driving unit configured to drive the amplified rising clock and the amplified falling clock, thereby generating a rising output clock and a falling output clock, respectively.

These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a block diagram illustrating a structure of a DLL circuit according to one embodiment.

FIG. 2 is a diagram illustrating a structure of an amplifying unit shown that can be included in the circuit illustrated in FIG. 1;

FIG. 3 is a diagram illustrating a detailed structure of a first differential amplifier that can be included in the circuit illustrated in FIG. 2; and

FIG. 4 is a diagram illustrating a structure of a duty cycle control unit that can be included in the circuit illustrated in FIG. 1;

### DETAILED DESCRIPTION

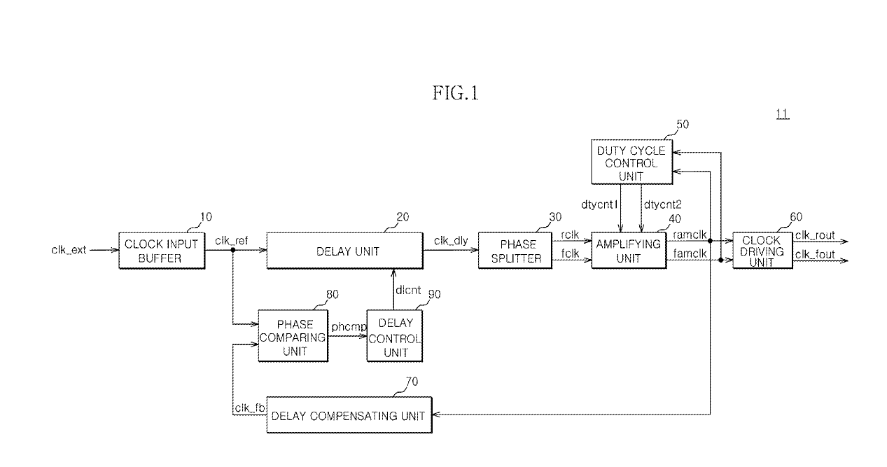

Referring to FIG. 1, a DLL circuit 11 according to one embodiment can include a clock input buffer 10, a delay unit 20, a phase splitter 30, an amplifying unit 40, a duty cycle control unit 50, a clock driving unit 60, a delay compensating unit 70, a phase comparing unit 80, and a delay control unit 90.

The clock input buffer 10 can be configured to buffer an external clock (clk_ext), thereby generating a reference clock (clk_ref). The delay unit 20 can be configured to delay the reference clock (clk_ref) in response to a delay control signal (dlcnt), thereby generating a delay clock (clk_dly). The phase splitter 30 can be configured to control the phase of the delay clock (clk_dly), thereby generating a rising clock (rclk) and a falling clock (fclk). The amplifying unit 40 can be configured to perform differential amplification on the rising clock (rclk) and the falling clock (fclk) in response to first and second duty control signals (dtycnt1) and (dtycnt2), thereby generating an amplified rising clock (ramclk) and an amplified falling clock (famclk). The duty cycle control unit 50 can be configured to detect the duty rates of the amplified rising clock (ramclk) and the amplified falling clock (famclk), thereby generating the first and second duty control signals (dtycnt1) and (dtycnt2).

The amplifying unit 40 and the duty cycle control unit 50 can form an independent feedback loop. The duty cycle control unit 50 can be fed back with an amplified rising clock (ramclk) and an amplified falling clock (famclk) from the amplifying unit 40. The duty cycle control unit 50 can be configured to detect the duty cycles thereof and generate the first and second duty control signals (dtycnt1) and (dtycnt2) to compensate for the duty cycles. The amplifying unit 40 can be configured to perform differential amplification on the rising clock (rclk) and the falling clock (fclk) in response to the first and second duty control signals (dtycnt1) and (dtycnt2) to compensate for the duty cycles of the rising clock (rclk) and the falling clock (fclk), and thereby generate the amplified rising clock (ramclk) and the amplified falling clock (famclk). When the operation of the feedback loop, formed by the amplifying unit 40 and the duty cycle control unit 50, is repeated in this way, the duty cycles of the amplified rising clock (ramclk) and the amplified falling clock (famclk) become constant.

The clock driving unit 60 can be configured to drive the amplified rising clock (ramclk) and the amplified falling clock (famclk), thereby generating a rising output clock (clk_rout) and a falling output clock (clk_fout), respectively. The delay compensating unit 70 can be configured to model the delay values of delay elements on a path of the amplified rising clock (ramclk) to a data output buffer, and assign a delay amount corresponding to the delay value to the amplified rising clock (ramclk), thereby generating a feedback clock (clk_fb).

The phase comparing unit 80 can be configured to transmit, to the delay control unit 90, a phase comparison signal (phcmp) that includes information on the phases of the reference clock (clk_ref) and the feedback clock (clk_fb). The delay control unit 90 can be configured to generate the delay control signal (dlcnt) according to the information included in the received phase comparison signal (phcmp), and to transmit the delay control signal (dlcnt) to the delay unit 20. Then, the delay unit 20 can be configured to control the delay amount assigned to the reference clock (clk_ref).

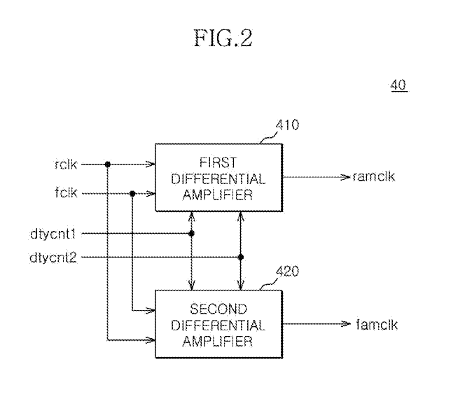

Referring to FIG. 2, the amplifying unit 40 can include a first differential amplifier 410 that can be configured to perform differential amplification on the rising clock (rclk) and the falling clock (fclk) in response to the first and second duty control signals (dtycnt1) and (dtycnt2), thereby generating the amplified rising clock (ramclk), and a second differential amplifier 420 that can be configured to perform differential amplification on the rising clock (rclk) and the falling clock (fclk) in response to the first and second duty control signals (dtycnt1) and (dtycnt2), thereby generating the amplified falling clock (famclk).

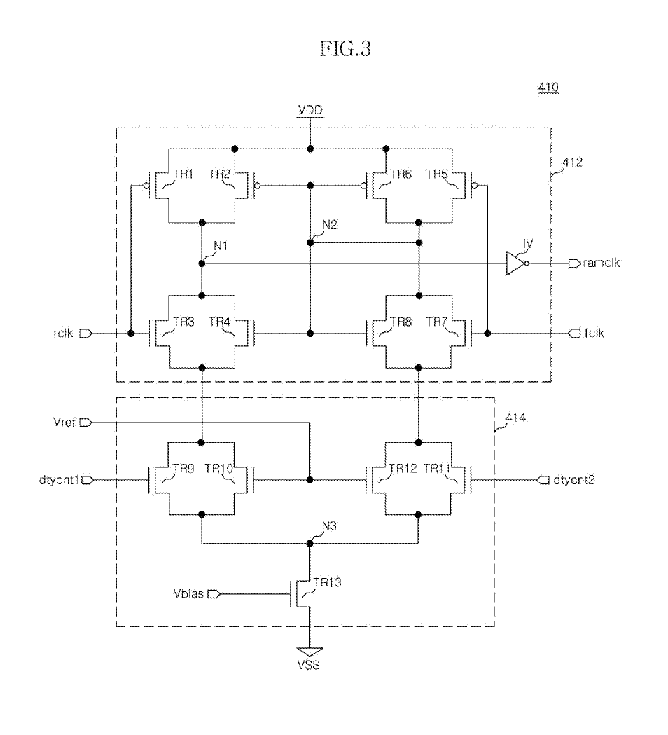

A first differential amplifier 410 and a second differential amplifier 420 can have the same structure except that the first duty control signal (dtycnt1) and the second duty control signal (dtycnt2) are input to opposite terminals and the rising clock (rclk) and the falling clock (fclk) are input to opposite terminals. Therefore, the structure and operation of only the first differential amplifier 410 will be described below with reference to FIG. 3.

Referring to FIG. 3, the first differential amplifier 410 can be configured to include an amplifying section 412 that performs differential amplification on both the rising clock (rclk) and the falling clock (fclk), thereby generating the amplified rising clock (ramclk), and a controlling section 414 that can be configured to control the operation of the amplifier 412 in response to a reference voltage Vref, a bias voltage Vbias, and the first and second duty control signals (dtycnt1) and (dtycnt2).

An amplifying section 412 can include first to eighth transistors TR1 to TR8, an inverter IV, and first and second nodes N1 and N2.

The first transistor TR1 can have a gate can be configured to receive the rising clock (rclk), a source supplied with an external power supply voltage VDD, and a drain coupled with the first node N1. The second transistor TR2 can have a gate coupled with the second node N2, a source supplied with the external power supply voltage VDD, and a drain coupled with the first node N1. The third transistor TR3 can have a gate configured to receive the rising clock (rclk), a drain coupled with the first node N1, and a source coupled with the controlling section 414. The fourth transistor TR4 can have a gate coupled with the second node N2, a drain coupled with the first node N1, and a source coupled with the controlling section 414.

The fifth transistor TR5 can have a gate configured to receive the falling clock (fclk), a source supplied with the external power supply voltage VDD, and a drain coupled with the second node N2. The sixth transistor TR6 can have a gate and a drain that are coupled with the second node N2, and a source supplied with the external power supply voltage VDD. The seventh transistor TR7 can have a gate configured to receive the falling clock (fclk), a drain coupled with the second node N2, and a source coupled with the controlling section 414. The eighth transistor TR8 can have a gate and a drain that are coupled with the second node N2, and a source coupled with the controlling section 414. The inverter IV can be configured to receive a voltage applied to the first node N1 and to output the amplified rising clock (ramclk).

A controlling section 414 can include the ninth to thirteenth transistors TR9 to TR13 and a third node N3.

The ninth transistor TR9 can have a gate configured to receive the first duty control signal (dtycnt1), a drain coupled with the sources of the third and fourth transistors TR3 and TR4 of the amplifying section 412, and a source coupled with the third node N3. The tenth transistor TR10 can have a gate supplied with the reference voltage Vref, a drain coupled with the sources of the third and fourth transistors TR3 and TR4, and a source coupled with the third node N3. The eleventh transistor TR11 can have a gate receiving the second duty control signal (dtycnt2), a drain coupled with the sources of the seventh and eighth transistors TR7 and TR8 of the amplifying section 412, and a source coupled with the third node N3. The twelfth transistor TR12 can have a gate supplied with the reference voltage Vref, a drain coupled with the sources of the seventh and eighth transistors TR7 and TR8, and a source coupled with the third node N3. The thirteenth transistor TR13 can have a gate supplied with the bias voltage Vbias, a drain coupled with the third node N3, and a source that is grounded.

In a first differential amplifier 410, configured with above-mentioned structure, when the voltage level of the rising clock (rclk) is at a high level and the voltage level of the falling clock (fclk) is at a low level, then the third transistor TR3 of the amplifying section 412 is turned on, and the fourth transistor TR4 is turned off. The first transistor TR1 is turned off, and the fifth transistor TR5 is turned on. As a result, the voltage level of the first node N1 is lower than that of the second node N2. Even when the fourth transistor TR4 and the eighth transistor TR8 are turned on, this state is maintained.

The first duty control signal (dtycnt1) can be a signal for lengthening a high-level period of the amplified rising clock (ramclk), and the second duty control signal (dtycnt2) can be a signal for shortening the high-level period of the amplified rising clock (ramclk). If the high-level period of the amplified rising clock (ramclk) is longer than a low-level period thereof, then the voltage level of the first duty control signal (dtycnt1) can become higher than that of the second duty control signal (dtycnt2). Therefore, the driving ability of the ninth transistor TR9 can be strengthened, and the period in which the voltage level of the first node N1 is lower than that of the second node N2 can be lengthened.

Thereafter, when the voltage level of the rising clock (rclk) turns to a low level and the voltage level of the falling clock (fclk) turns to a high level, the voltage level of the first node N1 can be higher than that of the second node N2. In this case, when the voltage level of the first duty control signal (dtycnt1) is kept higher than that of the second duty control signal (dtycnt2), the period in which the voltage level of the first node N1 is higher than that of the second node N2 is shortened, since the driving ability of the ninth transistor TR9 was strengthened.

The potential of the first node N1 formed in this way is inverted and output by the inverter IV, which should cause the period in which the amplified rising clock (ramclk) is at a high level to be lengthened.

In one embodiment, the high-level period of the amplified rising clock (ramclk) can be longer than the low-level period. It will be understood that, even when the high-level period of the amplified rising clock (ramclk) is shorter than the low-level period, the duty cycle of the amplified rising clock (ramclk) can be compensated by the structure and operation of the first differential amplifier 410. The second differential amplifier 420 can have the same structure and operation as the first differential amplifier 410.

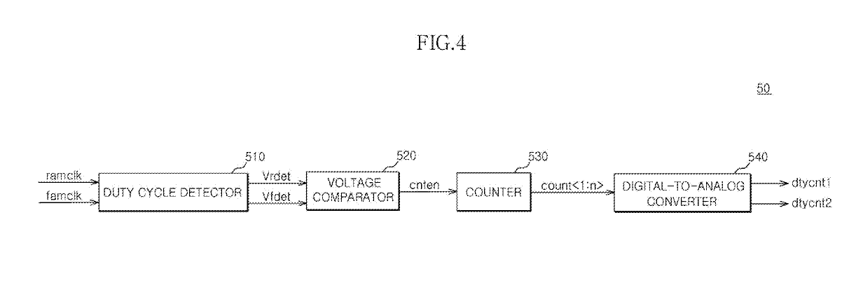

Referring to FIG. 4, a duty cycle control unit 50 can include a duty cycle detector 510, a voltage comparator 520, a counter 530, and a digital-to-analog converter 540.

The duty cycle detector 510 can be configured to detect the duty cycles of the amplified rising clock (ramclk) and the amplified falling clock (famclk), and can thereby generate a rising detection voltage Vrdet and a falling detection voltage Vfdet. The duty cycle detector 510 cay be implemented by a conventional duty accumulator. When a first period (for example, a high-level period) of the amplified rising clock (ramclk) is longer than a second period (for example, a low-level period), the duty cycle detector 510 can increase the level of the rising detection voltage Vrdet to be higher than the level of the falling detection voltage Vfdet. Since the amplified rising clock (ramclk) and the amplified falling clock (famclk) have opposite phases, the level of the falling detection voltage Vfdet is higher than the level of the rising detection voltage Vrdet when the first period of the amplified falling clock (famclk) is longer than the second period.

The voltage comparator 520 can be configured to compare the level of the rising detection voltage Vrdet with the level of the falling detection voltage Vfdet, thereby generating a count enable signal (cnten). The voltage comparator 520 can be implemented by a differential-amplifier-type comparator. The voltage comparator 520 can be configured to generate a count enable signal (cnten) that can be enabled according to whether the level of the rising detection voltage Vrdet is higher than the level of the falling detection voltage Vfdet.

The counter 530 can perform a counting operation in response to the count enable signal (cnten), thereby generating an n-bit count signal (count<1:n>). When the count enable signal (cnten) is enabled, the counter 530 can be configured to increase the logical value of the n-bit count signal (count<1:n>). When the count enable signal (cnten) is disabled, the counter 530 can be configured to decrease the logical value of the n-bit count signal (count<1:n>).

The digital-to-analog converter 540 can be configured to generate the first and second duty control signals (dtycnt1) and (dtycnt2) in response to the n-bit count signals (count<1:n>). The digital-to-analog converter 540 can be configured to convert the n-bit count signals (count<1:n>), which are digital signals, into the first and second duty control signals (dtycnt1) and (dtycnt2), which are analog signals. The first and second duty control signals (dtycnt1) and (dtycnt2) can have voltage levels corresponding to the logical values of the n-bit count signals (count<1:n>), respectively.

As described above, a DLL circuit according to the embodiment described herein can include differential amplifiers that perform differential amplification on a rising clock and a falling clock output from a phase splitter to generate an amplified rising clock and an amplified falling clock, respectively. The DLL circuit can control the operations of the differential amplifiers according to the duty cycles of the amplified rising clock and the amplified falling clock, thereby generating clocks having a constant duty cycle. Thus, when the DLL circuit drives the amplified rising clock and the amplified falling clock, thereby generating a rising output clock and a falling output clock, and transmits the rising output clock and the falling output clock to a data output buffer, a semiconductor integrated circuit can stably process data. That is, the DLL circuit according to the embodiments described herein can generate clocks having a constant duty cycle, which enables a semiconductor integrated circuit to perform a stable data processing operation.

While certain embodiments have been described above, it will be understood that the embodiments described are by way of example only. Accordingly, the apparatus and methods described herein should not be limited based on the described embodiments. Rather, the apparatus and methods described herein should only be limited in light of the claims that follow when taken in conjunction with the above description and accompanying drawings.

What is claimed is:

1. A DLL circuit comprising:
a phase splitter configured to control the phase of a delay clock, thereby generating a rising clock and a falling clock;
an amplifying unit configured to perform differential amplification on the rising clock and the falling clock in response to first and second duty control signals, thereby generating an amplified rising clock and an amplified falling clock; and
a duty cycle control unit configured to detect the duty rates of the amplified rising clock and the amplified falling clock, thereby generating the first and second duty control signals.

2. The DLL circuit of claim 1, wherein, when the voltage level of the first duty control signal is higher than that of the second duty control signal, the amplifying unit is configured to shorten a first period of the amplified rising clock, and when the voltage level of the first duty control signal is lower than that of the second duty control signal, the amplifying unit is configured to shorten the first period of the amplified falling clock.

3. The DLL circuit of claim 2, wherein the amplifying unit comprises:
a first differential amplifier configured to perform differential amplification on the rising clock and the falling clock in response to the first and second duty control signals, thereby generating the amplified rising clock; and
a second differential amplifier configured to perform differential amplification on the rising clock and the falling clock in response to the first and second duty control signals, thereby generating the amplified falling clock.

4. The DLL circuit of claim 3, wherein the first differential amplifier comprises:
an amplifying section configured to perform differential amplification on the rising clock and the falling clock, thereby generating the amplified rising clock; and
a controlling section configured to control the operation of the amplifier in response to a reference voltage, a bias voltage, and the first and second duty control signals.

5. The DLL circuit of claim 3, wherein the second differential amplifier comprises:
an amplifying configured to perform differential amplification on the rising clock and the falling clock, thereby generating the amplified falling clock; and
a controlling section configured to control the operation of the amplifier in response to a reference voltage, a bias voltage, and the first and second duty control signals.

6. The DLL circuit of claim 2, wherein, when the first period of the amplified rising clock is shorter than a second period, the duty cycle control unit is configured to increase the voltage level of the first duty control signal to be higher than the voltage level of the second duty control signal, and when the first period of the amplified falling clock is shorter than the second period, the duty cycle control unit is configured to increase the voltage level of the second duty control signal to be higher than the voltage level of the first duty control signal.

7. The DLL circuit of claim 6, wherein the duty cycle control unit comprises:
a duty cycle detector configured to detect the duty cycles of the amplified rising clock and the amplified falling clock, thereby generating a rising detection voltage and a falling detection voltage, respectively;
a voltage comparator configured to compare the level of the rising detection voltage with the level of the falling detection voltage, thereby generating a count enable signal;
a counter configured to perform a counting operation in response to the count enable signal, thereby generating a plural-bit count signal; and
a digital-to-analog converter configured to generate the first and second duty control signals in response to the plural-bit count signal.

8. The DLL circuit of claim 7, wherein, when the first period of the amplified rising clock is longer than the second period, the duty cycle detector is configured to increase the level of the rising detection voltage to be higher than the level of the falling detection voltage, and when the first period of the amplified falling clock is longer than the second period, the duty cycle detector is configured to increase the level of the falling detection voltage to be higher than the level of the rising detection voltage.

9. The DLL circuit of claim 7, wherein, when the count enable signal is enabled, the counter is configured to increase the logical value of the plural-bit count signal, and when the count enable signal is disabled, the counter is configured to decrease the logical value of the plural-bit count signal.

10. The DLL circuit of claim 7, wherein the digital-to-analog converter is configured to generate the first duty control signal and the second duty control signal having voltage levels corresponding to the logical values of the plural-bit count signals.

11. The DLL circuit of claim 1, further comprising:
a clock input buffer configured to buffer an external clock, thereby generating a reference clock;
a delay unit configured to delay the reference clock in response to a delay control signal, thereby generating the delay clock;
a clock driving unit configured to drive the amplified rising clock and the amplified falling clock, thereby generating a rising output clock and a falling output clock, respectively;
a delay compensating unit configured to delay the amplified rising clock by a predetermined amount of time, thereby generate a feedback clock;
a phase comparing unit configured to compare the phase of the reference clock with the phase of the feedback clock, thereby generating a phase comparison signal; and
a delay control unit configured to generate the delay control signal in response to the phase comparison signal.

12. A DLL circuit comprising:
an amplifying unit configured to perform differential amplification on a rising clock and a falling clock in response to first and second duty control signals, thereby generating an amplified rising clock and an amplified falling clock;
a duty cycle control unit configured to detect the duty rates of the amplified rising clock and the amplified falling clock, thereby generating the first and second duty control signals; and
a clock driving unit configured to drive the amplified rising clock and the amplified falling clock, thereby generating a rising output clock and a falling output clock, respectively.

13. The DLL circuit of claim 12, wherein, when the voltage level of the first duty control signal is higher than that of the second duty control signal, the amplifying unit is configured to shorten a first period of the amplified rising clock, and when the voltage level of the first duty control signal is lower than that of the second duty control signal, the amplifying unit is configured to shorten the first period of the amplified falling clock.

14. The DLL circuit of claim 13, wherein the amplifying unit comprises:
a first differential amplifier configured to perform differential amplification on the rising clock and the falling clock in response to the first and second duty control signals, thereby generating the amplified rising clock; and
a second differential amplifier configured to perform differential amplification on the rising clock and the falling clock in response to the first and second duty control signals, thereby generating the amplified falling clock.

15. The DLL circuit of claim 14, wherein the first differential amplifier comprises:
an amplifying section configured to perform differential amplification on the rising clock and the falling clock, thereby generating the amplified rising clock; and
a controlling section configured to control the operation of the amplifier in response to a reference voltage, a bias voltage, and the first and second duty control signals.

16. The DLL circuit of claim 14, wherein the second differential amplifier comprises:
an amplifying section configured to perform differential amplification on the rising clock and the falling clock, thereby generating the amplified falling clock; and
a controlling section configured to control the operation of the amplifier in response to a reference voltage, a bias voltage, and the first and second duty control signals.

17. The DLL circuit of claim 14, wherein, when the first period of the amplified rising clock is shorter than a second period, the duty cycle control unit is configured to increase the voltage level of the first duty control signal to be higher than the voltage level of the second duty control signal, and when the first period of the amplified falling clock is shorter than the second period, the duty cycle control unit is configured to increase the voltage level of the second duty control signal to be higher than the voltage level of the first duty control signal.

18. The DLL circuit of claim 17, wherein the duty cycle control unit comprises:
a duty cycle detector configured to detect the duty cycles of the amplified rising clock and the amplified falling clock, thereby generating a rising detection voltage and a falling detection voltage, respectively;
a voltage comparator configured to compare the level of the rising detection voltage with the level of the falling detection voltage, thereby generating a count enable signal;
a counter configured to perform a counting operation in response to the count enable signal, thereby generating a plural-bit count signal; and
a digital-to-analog converter configured to generate the first and second duty control signals in response to the plural-bit count signal.

19. The DLL circuit of claim 18, wherein, when the first period of the amplified rising clock is longer than the second period, the duty cycle detector is configured to increase the level of the rising detection voltage to be higher than the level of the falling detection voltage, and when the first period of the amplified falling clock is longer than the second period, the duty cycle detector is configured to increase the level of the falling detection voltage to be higher than the level of the rising detection voltage.

20. The DLL circuit of claim 18, wherein, when the count enable signal is enabled, the counter is configured to increase the logical value of the plural-bit count signal, and when the count enable signal is disabled, the counter is configured to decrease the logical value of the plural-bit count signal.

21. The DLL circuit of claim 18, wherein the digital-to-analog converter is configured to generate the first duty control signal and the second duty control signal having voltage levels corresponding to the logical values of the plural-bit count signals.

22. The DLL circuit of claim 12, further comprising:
a clock input buffer configured to buffer an external clock, thereby generating a reference clock;
a delay unit configured to delay the reference clock in response to a delay control signal, thereby generating a delay clock;
a phase splitter configured to control the phase of the delay clock, thereby generating the rising clock and the falling clock;
a delay compensating unit configured to delay the amplified rising clock by a predetermined amount of time, thereby generating a feedback clock;
a phase comparing unit configured to compare the phase of the reference clock with the phase of the feedback clock, thereby generating a phase comparison signal; and
a delay control unit configured to generate the delay control signal in response to the phase comparison signal.
